(19) United States
(12) Patent Application Publication
(10) Pub. No.: US 2008/0096386 A1
(43) Pub. Date: Apr. 24, 2008

(54) METHOD OF FORMING A PHASE-CHANGEABLE LAYER AND METHOD OF MANUFACTURING A SEMICONDUCTOR MEMORY DEVICE USING THE SAME

(75) Inventors: Young-Lim PARK, Gyeonggi-do (KR); Sung-Lae CHO, Gyeonggi-do (KR); Byoung-Jae BAE, Gyeonggi-do (KR); Jin-Il LEE, Gyeonggi-do (KR); Hye-Young PARK, Gyeonggi-do (KR); Ji-Eun LIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/876,631

(22) Filed: Oct. 22, 2007

(30) Foreign Application Priority Data
Oct. 20, 2006 (KR) 2006-102415

(51) Int. Cl. H01L 21/02

(52) U.S. Cl. 438/680; 427/255.28; 257/E21.002

(57) ABSTRACT

A phase-changeable layer and a method of forming the same are disclosed. In the method, a first hydrogen gas is introduced into a reaction chamber into which a substrate is loaded at a first flow rate to form first plasma. A primary cyclic CVD process is carried out using precursors in the reaction chamber to form a lower phase-changeable layer having a first grain size on the substrate. A second hydrogen gas is introduced into the reaction chamber at a second flow rate less than the first flow rate to form second plasma. A secondary cyclic CVD process is carried out using the precursors in the reaction chamber to form an upper phase-changeable layer having a second grain size smaller than the first grain size on the substrate, thereby forming a phase-changeable layer. Thus, the phase-changeable layer may have strong adhesion strength with respect to a lower layer and good electrical characteristics.

### CROSS-REFERENCE TO RELATED APPLICATION

This application claims the benefit of foreign priority under 35 USC § 119 to Korean Patent Application No. 2006-102415 filed on Oct. 20, 2006, the contents of which are herein incorporated by reference in its entirety for all purposes.

### BACKGROUND

1. Field of Invention

Embodiments exemplarily described herein relate to methods of forming phase-changeable layers and methods of manufacturing semiconductor memory device using the same. More particularly, embodiments exemplarily described herein relate to a method of forming a phase-changeable layer using plasma that has good characteristics, a method of manufacturing a semiconductor memory device using the method.

2. Description of the Related Art

Generally, semiconductor memory devices are classified as either a volatile memory device (e.g., a dynamic random access memory (DRAM) device and a static random access memory (SRAM) device) or a non-volatile memory device (e.g., a flash memory device and an electrically erasable programmable read only memory (EEPROM) device) depending on whether data is stored or removed when a current is not provided to the memory device. Non-volatile memory devices, particularly flash memory devices, have been widely used as data-storing memory devices in digital camera, MP3 players, cellular phones, etc. However, because flash memory devices may require a relatively long period of time for reading/writing data, random access memory devices such as ferroelectric random access memory (FRAM) devices, magnetic random access memory (MRAM) devices, phase-changeable random access memory (PRAM) devices, etc., have been proposed as next generation memory devices.

The PRAM device is a type of non-volatile memory device that may store data using a resistance difference between a substantially amorphous crystalline structure and a substantially crystalline structure induced by phase transition of a chalcogenide compound. That is, the PRAM device may store the data as “0” and “1” using reversible phase transition of a phase-changeable layer such as the chalcogenide compound, which may include germanium-antimony-tellurium (Ge—Sb—Te; GST) in accordance with amplitude and a length of an applied pulse. Particularly, a reset current converting the substantially crystalline structure having a low resistance into the substantially amorphous crystalline structure having a high resistance, and a set current converting the substantially amorphous crystalline structure having the high resistance into the substantially crystalline structure having the low resistance may be transmitted from a transistor to the phase-changeable layer through a lower electrode, to thereby generate the phase transition. Here, an upper region of the lower electrode may be connected to the phase-changeable layer, and a lower region of the lower electrode may be connected to a contact making contact with the transistor. Conventional PRAM devices and methods of manufacturing the RPAM device are disclosed in Korean Patent No. 437458, Korean Patent Laid-Open Publication No. 2005-31160, U.S. Pat. Nos. 5,825,046 and 5,596,522, etc.

In the conventional methods of manufacturing the PRAM device disclosed in the above-mentioned documents, the phase-changeable layer including the GST may be formed by a physical vapor deposition (PVD) process such as a sputtering process, an evaporation deposition process, etc. However, a growth speed of the phase-changeable layer may not be accurately controlled by the PVD process. Thus, the phase-changeable layer may not have a dense crystalline structure or a face-centered cubic (FCC) crystalline structure—both desirable properties to ensure a device having good electrical characteristics. Further, when the phase-changeable layer is formed by the PVD process, a composition ratio among germanium (Ge), antimony (Sb) and tellurium (Te) in the phase-changeable layer may not be precisely controlled. As a result, characteristics of the phase-changeable layer may be further degraded. Furthermore, because a deposition speed of the phase-changeable material in the PVD process can be undesirably slow, the time and cost associated with forming the phase-changeable layer may be undesirably large. Particularly, although U.S. Pat. No. 5,596,522 can be understood to disclose, in detail, a method of forming a phase-changeable layer including germanium-antimony-tellurium (Ge—Sb—Te) by a sputtering process and an evaporation deposition process, U.S. Pat. No. 5,596,522 does not disclose a method of forming a phase-changeable layer using a chemical vapor deposition (CVD) process.

Further, while a phase-changeable layer formed by a CVD process may have a grain size of not less than about 50 nm and have good adhesion characteristics with respect to a lower layer, the phase-changeable layer formed by a CVD process may not have a suitably uniform electrical characteristic. In contrast, while the phase-changeable layer formed by the CVD process may have a grain size of no more than about 30 nm and have a suitably uniform electrical characteristic, the phase-changeable layer may have poor adhesion characteristics with respect to the lower layer and be lifted off from the lower layer.

### SUMMARY

According to some embodiments, a method may be provided to form a phase-changeable memory device that has good adhesion strength and good electrical characteristics by properly controlling an amount of a hydrogen gas for forming plasma. According to some embodiments, the embodiments exemplarily described herein may be adapted to a method of manufacturing a semiconductor memory device.

One embodiment exemplarily described herein may be generally characterized as a method of forming a phase-changeable layer. The method may, for example, include loading a substrate into a reaction chamber, introducing a first hydrogen gas into the reaction chamber at a first flow rate to form a first plasma, performing a primary cyclic chemical vapor deposition (CVD) process using a first precursor, a second precursor and a third precursor in the reaction chamber in which the first plasma is formed to form a lower phase-changeable layer on the substrate, the lower phase-changeable layer including grains having a first grain size, introducing a second hydrogen gas into the reaction chamber at a second flow rate less than the first flow rate to form a second plasma and performing a secondary cyclic CVD process using the first, the second and the third precursors in the reaction chamber in which the second plasma is formed to form an upper phase-changeable layer on the lower phase-changeable layer. The upper phase-changeable layer includes grains having a second grain size less than the first size.

Another embodiment exemplarily described herein may be generally characterized as a method of forming a semiconductor memory device. The method may, for example, include forming a lower electrode on a substrate, forming a lower phase-changeable layer on the lower electrode, the lower phase-changeable layer including a germanium-antimony-tellurium alloy, wherein grains of the lower phase-changeable layer have a first grain size, forming an upper phase-changeable layer on the lower phase-changeable layer, the upper phase-changeable layer including a germanium-antimony-tellurium alloy, wherein grains of the upper phase-changeable layer have a second grain size less than the first grain size and forming an upper electrode on the upper phase-changeable layer. The lower phase-changeable layer may be formed by a primary CVD process using a germanium precursor, an antimony precursor and a tellurium precursor under a first plasma that is formed from a first hydrogen gas at a first flow rate. The upper phase-changeable layer may be formed by a secondary CVD process using a germanium precursor, an antimony precursor and a tellurium precursor under a second plasma that is formed from a second hydrogen gas at a second flow rate less than the first flow rate.

### BRIEF DESCRIPTION OF THE DRAWINGS

The above and other features of embodiments of the present invention will become readily apparent by reference to the following detailed description when considered in conjunction with the accompanying drawings, wherein:

FIG. 1 is a cross-sectional view illustrating a phase-changeable layer in accordance with some example embodiments;

FIG. 2 is a scanning electron microscope (SEM) picture showing a cross-section of a lower phase-changeable layer shown in FIG. 1;

FIG. 3 is a scanning electron microscope (SEM) picture showing a cross-section of an upper phase-changeable layer shown in FIG. 1;

FIG. 4 is a flow chart illustrating an exemplary method of forming the phase-changeable layer shown in FIG. 1;

FIG. 5 is a timing chart illustrating a process for forming the lower phase-changeable layer shown in FIG. 1; and

FIGS. 6 to 13 are cross-sectional views illustrating a method of manufacturing a semiconductor memory device in accordance with one example embodiment.

### DETAILED DESCRIPTION

Exemplary embodiments of the present invention will be described more fully hereinafter with reference to the accompanying drawings. These embodiments may, however, be realized in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the embodiments described herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Phase-Changeable Layer

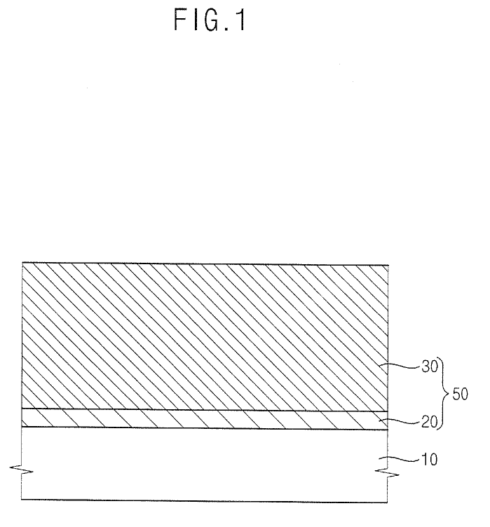

FIG. 1 is a cross-sectional view illustrating a phase-changeable layer in accordance with some example embodiments.

Referring to FIG. 1, a phase-changeable layer 50 may, for example, include a lower phase-changeable layer 20 formed on an object 10 and an upper phase-changeable layer 30 formed on the lower phase-changeable layer 20.

The object 10 may, for example, include a semiconductor substrate such as a silicon wafer, a silicon-on-insulator (SOI) substrate, a metal oxide single crystalline substrate (e.g., an aluminum oxide (Al₂O₃) single crystalline substrate, a strontium titanium oxide (SrTiO₃) single crystalline substrate, etc) or the like or a combination thereof. Further, an electrode (not shown), a conductive layer (not shown), a conductive layer pattern (not shown), an insulation layer (not shown) or an insulation layer pattern (not shown) may be formed on the object 10. Thus, the phase-changeable layer 50 may be formed directly on the object 10 or the electrode, the conductive layer, the conductive layer pattern, the insulation layer or the insulation layer pattern of the object 10.

The lower phase-changeable layer 20 is disposed on the object 10. In one embodiment, the lower phase-changeable layer 20 may, for example, include a phase-changeable material such as germanium-antimony-tellurium (Ge—Sb—Te) or the like. Further, a grain size of the lower phase-changeable layer 20 may be not less than about 50 nm. Furthermore, the lower phase-changeable layer 20 may have strong adhesion strength with respect to the object 10.

In one embodiment, the lower phase-changeable layer 20 may be formed by a primary cyclic chemical vapor deposition (CVD) process using a first precursor, a second precursor and a third precursor under a first plasma that is formed from a first hydrogen gas having a first flow rate. The first precursor, the second precursor and the third precursor may include a germanium precursor, an antimony precursor and a tellurium precursor, respectively. Further, the first flow rate of the first hydrogen gas used for forming the first plasma may be about 3.1 times to about 6.0 times greater than a flow rate of a first argon gas also used for forming the first plasma.

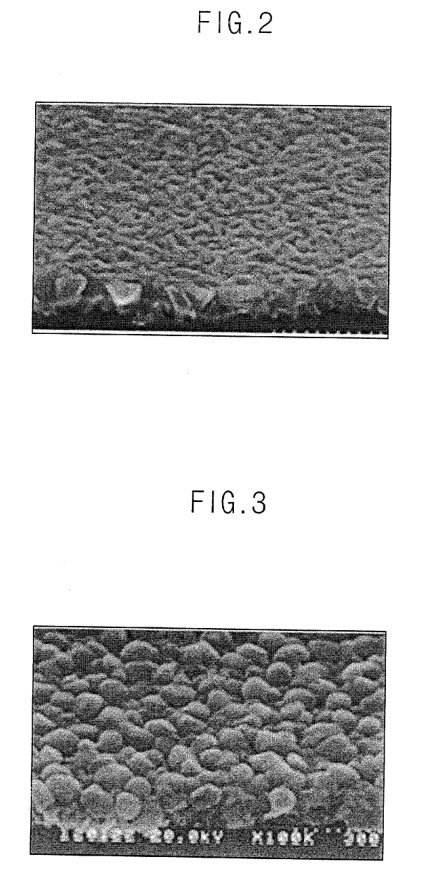

FIG. 2 is a scanning electron microscope (SEM) picture showing a cross-section of the lower phase-changeable layer 20 of the phase-changeable layer 50 in FIG. 1. Formed as exemplarily described above using the first plasma, the lower phase-changeable layer 20 may have rapidly grown spherical grains as shown in FIG. 2. The grains may have a size of about 50 nm to about 80 nm. In one embodiment, the grains may have a size of about 60 nm to about 70 nm.

Referring to back to FIG. 1, the upper phase-changeable layer 30 is arranged on the lower phase-changeable layer 20. In one embodiment, the upper phase-changeable layer 30 may include a phase-changeable material such as germanium-antimony-tellurium (Ge—Sb—Te) or the like. Further, the upper phase-changeable layer 30 may have a grain size below about 30 nm. In one embodiment, the upper phase-changeable layer 30 may prevent etching damages of the lower phase-changeable layer 20 and also ensure that the phase-changeable layer 50 has good electrical characteristics.

In one embodiment, the upper phase-changeable layer 30 may be formed by a secondary cyclic chemical vapor deposition (CVD) process using the first precursor, the second precursor and the third precursor under a second plasma that is formed from a second hydrogen gas having a second flow rate. The second flow rate of the second hydrogen gas used for forming the second plasma may be about 0.2 times to about 0.4 times greater than a second flow rate of a second argon gas also used for forming the second plasma.

FIG. 3 is a scanning electron microscope (SEM) picture showing a cross-section of the upper phase-changeable layer 30 of the phase-changeable layer 50 in FIG. 1. Formed as exemplarily described above using the second plasma, the upper phase-changeable layer 30 may have minute columnar grains as shown in FIG. 3. In one embodiment, the upper phase-changeable layer 30 may not have spaces between the minute columnar grains, whereas spaces may be present between the spherical grains of the lower phase-changeable layer 20. The columnar grains of the upper phase-changeable layer 30 may have a size of about 10 nm to about 30 nm. In one embodiment, the columnar grains of the upper phase-changeable layer 30 may have a size of about 20 nm to about 30 nm.

Referring back to FIG. 1, a thickness ratio of the upper phase-changeable layer 30 with respect to the lower phase-changeable layer 20 within the phase-changeable layer 50 may be about 8:1 to about 12:1. In one embodiment, the thickness ratio of the upper phase-changeable layer 30 with respect to the lower phase-changeable layer 20 within the phase-changeable layer 50 may be about 8:1 to about 10:1. Such a range of thickness ratios may provide the phase-changeable layer 50 with strong adhesion strength with respect to the object 10 and good electrical characteristics.

Exemplary Method of Forming a Phase-Changeable Layer

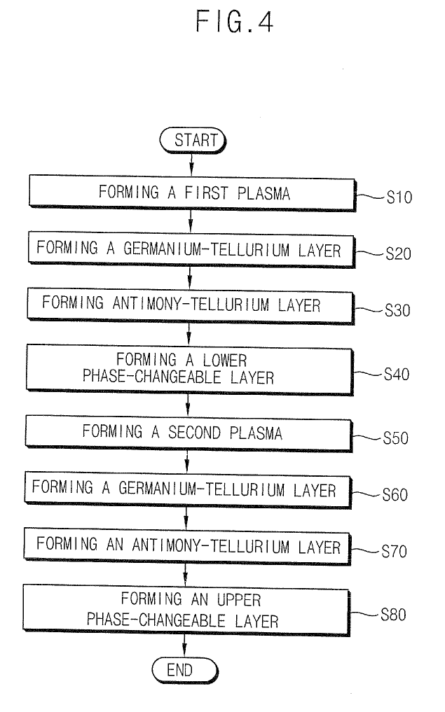

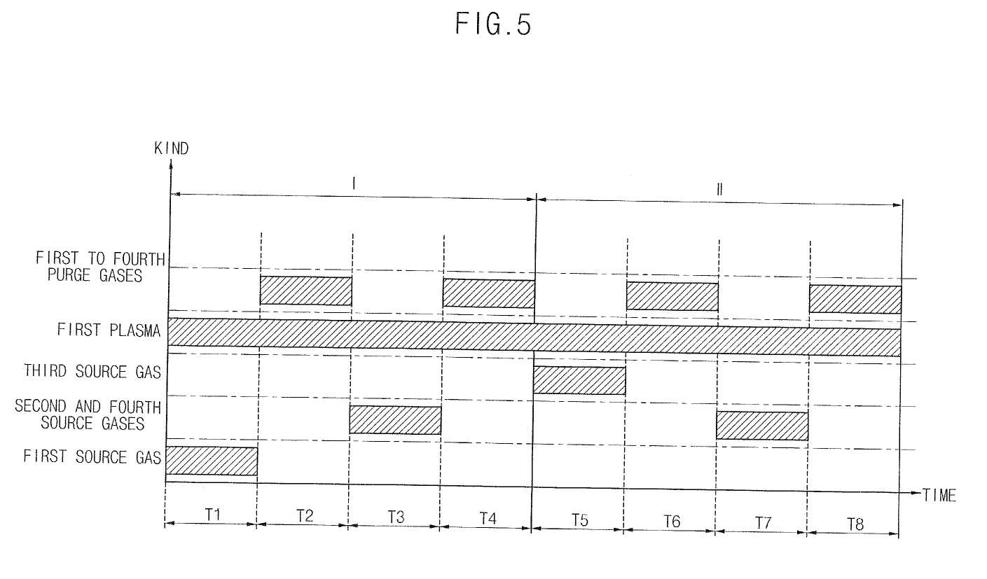

FIG. 4 is a flow chart illustrating a method of forming the phase-changeable layer shown in FIG. 1. FIG. 5 is a timing chart illustrating a process for forming the lower phase-changeable layer.

Referring to FIGS. 4 and 5, in step S10, an object, on which a phase-changeable layer is to be formed, is loaded into a reaction chamber. A first plasma is then formed in the reaction chamber.

In one embodiment, the first plasma formed over the object in the reaction chamber may include a first hydrogen plasma formed from a first hydrogen gas that is introduced into the reaction chamber at a first flow rate. For example, the first hydrogen plasma may be formed in the reaction chamber by introducing the first hydrogen gas into the reaction chamber at the first flow rate of about 300 sccm to about 800 sccm. In one embodiment, the first flow rate may be about 400 sccm to about 600 sccm.

In one embodiment, the first plasma may further include a first argon plasma formed from a first argon gas that is introduced into the reaction chamber at a third flow rate. For example, the first argon plasma may be formed by introducing the first argon gas into the reaction chamber at a third flow rate of about 100 sccm to about 200 sccm. Thus, the first flow rate of the first hydrogen gas may be about 3.1 times to about 6 times greater than the third flow rate of the first argon gas. In one embodiment, the first flow rate of the first hydrogen gas may be about 3.5 times to about 5.0 times greater than the third flow rate of the first argon gas.

The first plasma may be formed by preheating the first hydrogen gas and the first argon gas introduced into the reaction chamber for about 30 seconds to about 90 seconds. In one embodiment, the first hydrogen gas and the first argon gas introduced into the reaction chamber may be preheated for about 60 seconds. The preheated first hydrogen gas and the preheated first argon gas may be stabilized for about 1 second to about 3 seconds. In one embodiment, the preheated first hydrogen gas and the preheated first argon gas may be stabilized for about 2 seconds. An electric power of about 30 watts of about 150 watts, preferably about 60 watts to about 90 watts may be applied to the stabilized first hydrogen gas and the stabilized first argon gas for about 5 seconds to about 15 seconds to form the first plasma including a first hydrogen plasma and a first argon plasma over the object. In one embodiment, the electric power may be applied to the stabilized first hydrogen gas and the stabilized first argon gas for about 10 seconds. The first plasma may be continuously formed in the reaction chamber during forming a lower phase-changeable layer on the object.

In step S20, a germanium-tellurium layer is subsequently formed on the object in the reaction chamber in which the first plasma is formed.

In one embodiment, a first source gas including a first material such as germanium may be introduced into the reaction chamber in which the first plasma is formed for a time duration T1. The first source gas may be applied to the object together with a first carrier gas from a first source gas canister. The first source gas canister may have a normal temperature. Further, the first carrier gas may include an inert gas such as argon. The first carrier gas may be introduced into the reaction chamber at a flow rate of about 50 sccm to about 200 sccm. In one embodiment, the first carrier gas may be introduced into the reaction chamber at a flow rate of about 100 sccm. The time duration T1 of the first source gas including the first material may be about 0.1 seconds to about 2.0 seconds. In one embodiment, the time duration T1 of the first source gas is about 1.0 second. The first source gas may correspond to a first precursor including a germanium precursor. Germanium precursors may, for example, include Ge(i-Pr)₃H, GeCl₄, Ge(Me)₄, Ge(Me)₄N₃, Ge(Et)₄, Ge(Me)₃NEt₂, Ge(i-Bu)₃H, Ge(nBu)₄, Sb(GeEt₃)₃, Ge(Cp)₂, or the like, either alone or as a mixture.

An electric power of about 30 watts to about 150 watts is applied to the reaction chamber under a low pressure of about 2 Torr to about 5 Torr, preferably about 3 Torr, when introducing the first source gas to chemically deposit germanium on the object, thereby forming a germanium layer. In one embodiment, an electric power of about 50 watts to about 90 watts may be applied to the reaction chamber when forming the germanium layer. In one embodiment, the first source gas may be introduced under a low pressure of about 3 Torr when forming the germanium layer. The reaction chamber may have an internal temperature of about 100° C. to about 200° C. In one embodiment, the reaction chamber may have an internal temperature of about 150° C.

A first purge gas is then introduced into the reaction chamber for a time duration T2. In one embodiment, the time duration T2 of the first purge gas may be about 0.1 seconds to about 2.0 seconds. In another embodiment, the time duration T2 of the first purge gas may be about 1 second. The first purge gas may, for example, include a hydrogen gas and an argon gas. The first purge gas may be introduced into the reaction chamber at a flow rate of about 50 sccm to about 200 sccm. In one embodiment, the first purge gas may be introduced into the reaction chamber at a flow rate of about 100 sccm.

A second source gas including a second material such as tellurium is introduced into the reaction chamber for a time duration T3. The second source gas may be supplied from a second source gas canister having a temperature of about 30° C. to about 40° C. The second source gas may be introduced into the reaction chamber together with a second carrier gas. The second carrier gas may, for example, include argon gas. The second carrier gas may be introduced into the reaction chamber at a flow rate of about 100 sccm. The time duration T3 of the second source gas including the first material may be about 0.1 seconds to about 1.0 second. In one embodiment, the time duration T3 of the second source gas including the first material may be about 0.4 seconds to about 0.8 seconds. The second source gas may correspond to a third precursor including a tellurium precursor. The tellurium precursor may, for example, include Te(iBu)₂, TeCl₄, Te(Me)₂, Te(Et)₂, Te(nPr)₂, Te(iPr)₂, Te(tBu)₂, or the like, either alone or as a mixture. In one embodiment, Te(iBu)₂ may be advantageously used as the tellurium precursor.

An electric power of about 30 watts to about 150 watts is applied to the reaction chamber under a low pressure of about 2 Torr to about 5 Torr when introducing the second source gas to chemically deposit tellurium on the germanium layer. Accordingly, the tellurium may be chemically reacted with the germanium layer to form a germanium-tellurium layer on the object. In one embodiment, a content ratio between germanium and tellurium in the germanium-tellurium layer may be adjusted by controlling the time duration T1 of the first source gas and/or the time duration T3 of the second source gas.

After forming the germanium-tellurium layer on the object, a second purge gas is then introduced into the reaction chamber for a time duration T4. In one embodiment, the time duration T4 of the second purge gas may be about 0.1 seconds to about 2.0 seconds. In another embodiment, the time duration T4 of the second purge gas may be about 1 second. Further, the second purge gas may, for example, include a hydrogen gas and an argon gas. The second purge gas may be introduced into the reaction chamber at a flow rate of about 50 sccm to about 200 sccm. In one embodiment, the second purge gas may be introduced into the reaction chamber at a flow rate of about 100 sccm.

In step S30, an antimony-tellurium layer is then formed on the germanium-tellurium layer in the reaction chamber in which the first plasma is formed.

In one embodiment, a third source gas including antimony may be introduced into the reaction chamber for a time duration T5. The first source gas may be supplied from a third source gas canister having a temperature of about 30° C. to about 40° C. The third source gas may be applied to the germanium-tellurium layer with a third carrier gas. The third carrier gas may, for example, include an argon gas. Further, the third carrier gas may be introduced into the reaction chamber at a flow rate of about 100 sccm. The time duration T5 of the third source gas may be about 0.1 seconds to about 1.0 second. In one embodiment, the time duration T5 of the third source gas may be about 0.4 seconds to about 0.8 seconds. The third source gas may correspond to a second precursor including an antimony precursor. The antimony precursor may, for example, include Sb(iBu)₃, SbCl₃, SbCl₅, Sb(Me)₃, Sb(Et)₃, Sb(nPr)₃, Sb(tBu)₃, Sb[N(Me)₂]₃, Sb(Cp)₃, or the like, either alone or as a mixture. In one embodiment, Sb(iBu)₃ may be advantageously used as the antimony precursor.

An electric power of about 30 watts to about 150 watts is applied to the reaction chamber under a low pressure of about 2 Torr to about 5 Torr when introducing the third source gas to chemically deposit antimony on the germanium-tellurium layer, thereby forming an antimony layer on the germanium-tellurium layer. A thickness of the antimony layer may be sufficient to allow antimony to diffuse into the germanium-tellurium layer.

A third purge gas is then introduced into the reaction chamber for a time duration T6. In one embodiment, the time duration T6 of the third purge gas may be about 0.1 seconds to about 2.0 seconds. In another embodiment, the time duration T6 of the third purge gas may be about 1 second. Further, the third purge gas may, for example, include a hydrogen gas and an argon gas. The third purge gas may be introduced into the reaction chamber at a flow rate of about 50 sccm to about 200 sccm. In one embodiment, the third purge gas may be introduced into the reaction chamber at a flow rate of about 100 sccm.

A fourth source gas including tellurium is introduced into the reaction chamber for a time duration T7. The fourth source gas may include a tellurium precursor including tellurium. In one embodiment, the fourth source gas may be substantially the same as the second source gas. The tellurium precursor may, for example, include Te(iBu)₂, TeCl₄, Te(Me)₂, Te(Et)₂, Te(nPr)₂, Te(iPr)₂, Te(tBu)₂, or the like, either alone or as a mixture.

In one embodiment, the fourth source gas may be supplied from a fourth source gas canister having a temperature of about 30° C. to about 40° C. In another embodiment, the second source gas and the fourth source gas may be supplied from the same source gas canister. In a further embodiment, the fourth source gas may be introduced into the reaction chamber together with a fourth carrier gas. The fourth carrier gas may, for example, include an argon gas. The fourth carrier gas may be introduced into the reaction chamber at a flow rate of about 100 sccm. The time duration T7 of the fourth source gas may be about 0.1 seconds to about 1.0 second. In one embodiment, the time duration T7 of the fourth source gas may be about 0.4 seconds to about 0.8 seconds. An electric power of about 30 watts to about 150 watts is applied to the reaction chamber under a low pressure of about 2 Torr to about 5 Torr when introducing the fourth source gas to chemically deposit tellurium on the antimony layer. Accordingly, the tellurium may be chemically reacted with antimony to form an antimony-tellurium layer on the germanium-tellurium layer. Additionally, a fourth purge gas may be introduced into the reaction chamber for a time duration T8.

In one embodiment, a content ratio between the antimony and the tellurium in the antimony-tellurium layer may be adjusted by controlling the time duration T5 of the third source gas and/or the time duration T7 of the fourth source gas.

In step S40, the steps S20 and S30 are repeated at least once to form the lower phase-changeable layer 20 including germanium-antimony-tellurium on the object.

In one embodiment, a first unit process I for forming the germanium-tellurium layer and a second unit process II for forming the antimony-tellurium layer may be repeated to form a lower phase-changeable layer having a desired thickness on the object.

Furthers the antimony-tellurium layer and the germanium-tellurium layer may have thicknesses for allowing antimony, tellurium and germanium to diffuse into an adjacent layer. Thus, when the antimony-tellurium layer and the germanium-tellurium layer are repeatedly stacked, the stacked layers may diffuse into each other, thereby forming the lower phase-changeable layer 20 including germanium-antimony-tellurium.

For example, when the first unit process I and the second unit process II is repeatedly carried out five times, a lower phase-changeable layer 20 having a thickness of about 80 Å to about 120 Å may be formed on the object.

According to one exemplary embodiment, the first unit process I and the second unit process II may be alternately performed once or at least twice. For example, a sequence of performing the first unit process I, then performing the second unit process II, then performing the first unit process I and then performing the second unit process II may be carried out. Or, a sequence performing the first unit process I, then performing the first unit process I again, then performing the second unit process II, then performing the second unit process II again may be carried out. Alternatively, a sequence of performing the second unit process II, then performing the first unit process I, then performing the second unit process II and then performing the first unit process I may be carried out. Or, a sequence of performing the second unit process II, then performing the second unit process II, then performing the first unit process I and then performing the first unit process I may be carried out.

The lower phase-changeable layer 20, formed under the first plasma conditions exemplarily described above, may include a germanium-antimony-tellurium alloy with grains having a grain size of no less than about 50 nm. In one embodiment, the grain size of the lower phase-changeable layer 20 (also referred to herein as the “first grain size”) may be about 50 nm to about 80 nm. In another embodiment, the first grain size of the lower phase-changeable layer 20 may be about 60 nm to about 70 nm. Because the lower phase-changeable layer 20 formed from the first plasma may have rapidly growing spherical grains, the lower phase-changeable layer 20 may have strong adhesion strength with respect to the object. However, because the lower phase-changeable layer 20 has spaces between the grains, the lower phase-changeable layer 20 may have relatively poor electrical characteristics.

In step S50, a second plasma is then formed in the reaction chamber in which the object having the lower phase-changeable layer 20 is received.

In one embodiment, the second plasma in the reaction chamber may include a second hydrogen plasma formed by introducing a second hydrogen gas into the reaction chamber at a second flow rate. For example, the second hydrogen plasma may be formed in the reaction chamber by introducing the second hydrogen gas into the reaction chamber at the second flow rate of about 60 sccm to about 120 sccm. Thus, the aforementioned first flow rate of the first hydrogen gas may be about 3 times to about 6 times greater than the second flow rate of the second hydrogen gas.

In one embodiment, the second plasma in the reaction chamber may further include a second argon plasma formed by introducing a second argon gas into the reaction chamber at a fourth flow rate. For example, the second argon plasma may be formed in the reaction chamber by introducing the second argon gas into the reaction chamber at the fourth flow rate of about 230 sccm to about 500 sccm. Thus, the aforementioned second flow rate of the second hydrogen gas may be about 0.2 times to about 0.4 times greater than the fourth flow rate of the second argon gas.

In one embodiment, the second plasma may be formed by preheating the second hydrogen gas and the second argon gas introduced into the reaction chamber for about 30 seconds to about 90 seconds. In another embodiment, the second hydrogen gas and the second argon gas introduced into the reaction chamber may be preheated for about 60 seconds. The preheated second hydrogen gas and the preheated second argon gas may be stabilized for about 1 second to about 3 seconds. In one embodiment, the preheated second hydrogen gas and the preheated second argon gas may be stabilized for about 2 seconds. An electric power of about 30 watts to about 150 watts may be applied to the stabilized second hydrogen gas and the stabilized second argon gas for about 5 seconds to about 15 seconds to thereby form the second plasma including a second hydrogen plasma and a second argon plasma over the lower phase-changeable layer 20. In one embodiment, an electric power of about 60 watts to about 90 watts may be applied to the stabilized second hydrogen gas and the stabilized second argon gas. In another embodiment, the electric power may be may be applied to the stabilized second hydrogen gas and the stabilized second argon gas for about 10 seconds. Accordingly, the second plasma may be continuously formed in the reaction chamber during forming an upper phase-changeable layer 30 on the lower phase-changeable layer 20.

In step S60, a germanium-tellurium layer is then formed on the lower phase-changeable layer 20 in the reaction chamber in which the second plasma is formed.

In one embodiment, the germanium-tellurium layer may be formed by a cyclic CVD process using a germanium precursor and a tellurium precursor under the second plasma atmosphere. In one embodiment, the process for forming the germanium-tellurium layer may be substantially the same as that illustrated in step S20. Thus, a detailed description with respect to such a process is omitted for the sake of brevity.

In step S70, an antimony-tellurium layer is then formed on the germanium-tellurium layer in the reaction chamber in which the second plasma is formed.

In one embodiment, the antimony-tellurium layer may be formed by a cyclic CVD process using an antimony precursor and a tellurium precursor under the second plasma atmosphere. In one embodiment, the process for forming the antimony-tellurium layer may be substantially the same as that illustrated in step S30. Thus, a detailed description with respect to such a process is omitted for the sake of brevity.

In step S80, the steps S60 and S70 are repeated at least twice to form the upper phase-changeable layer 30. Accordingly, grains of the upper phase-changeable layer 30 may have a second grain size smaller than the first grain size of the grains in the lower phase-changeable layer 20.

In one embodiment, a first unit process for forming the germanium-tellurium layer and a second unit process for forming the antimony-tellurium layer may be repeated to form an upper phase-changeable layer 30 having a desired thickness on the lower phase-changeable layer 20. As a result, the phase-changeable layer 50 including the lower phase-changeable layer 20 and the upper phase-changeable layer 30, which are sequentially stacked, is completed.

In one embodiment, the thicknesses of the antimony-tellurium layer and the germanium-tellurium layer, which are used in forming the upper phase-changeable layer, may be sufficient to allow antimony, tellurium and germanium to diffuse into adjacent layers. Therefore, when the antimony-tellurium layer and the germanium-tellurium layers are repeatedly stacked, the upper phase-changeable layer 30 including germanium-antimony-tellurium may be formed.

For example, the first unit process and the second unit process may be repeated 50 times. As a result, an upper phase-changeable layer 30 having a thickness of about 700 Å to about 1,200 Å may be formed on the lower phase-changeable layer 20. Accordingly, the upper phase-changeable layer 30 may have a thickness that is about 8 times to about 12 times greater than the thickness of the lower phase-changeable layer 20.

The upper phase-changeable layer 30, formed under the second plasma conditions exemplarily described above, may include a germanium-antimony-tellurium alloy with minute columnar grains having a second grain size of about 10 nm to about 30 nm. In one embodiment, the second grain size may be about 20 nm to about 30 nm. Because the upper phase-changeable layer 30 may not have spaces between the grains, the upper phase-changeable layer 30 may not experience excessive etching damage during subsequent etching and cleaning processes. Further, the upper phase-changeable layer 30 may have relatively good electrical characteristics. Furthermore, the phase-changeable layer 50 including the lower phase-changeable layer 20 and the upper phase-changeable layer 30 may not be lifted off from the object.

Exemplary Method of Manufacturing a Semiconductor Memory Device

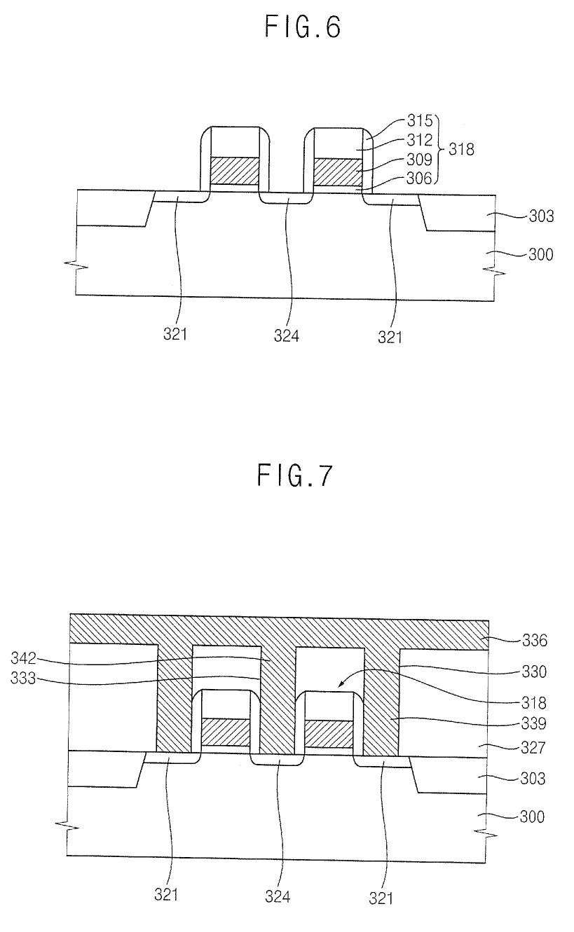

FIGS. 6 to 13 are cross-sectional views illustrating an exemplary method of manufacturing a semiconductor memory device in accordance with one example embodiment.

Referring to FIG. 6, isolation layers 303 are formed in a semiconductor substrate 300 to define an active region and a field region of the semiconductor substrate 300. In one embodiment, the isolation layers 303 may be formed by an isolation process such as a shallow trench isolation (STI) process, a local oxidation of silicon (LOCOS) process, or the like or a combination thereof. Further, the isolation layers 303 may include a material such as silicon oxide.

A gate insulation layer (not shown), a gate conductive layer (not shown) and a gate mask layer (not shown) are sequentially formed on the active region of the semiconductor substrate 300. In one embodiment, the gate insulation layer may include silicon oxide, a metal oxide having a high dielectric constant, or the like or a combination thereof. For example, the gate insulation layer may include silicon oxide, hafnium oxide, zirconium oxide, titanium oxide, tantalum oxide, aluminum oxide, or the like or a combination thereof. Further, the gate insulation layer may be formed by a thermal oxidation process, a chemical vapor deposition (CVD) process, a sputtering process, a plasma-enhanced CVD (PECVD) process, an atomic layer deposition (ALD) process, a high-density plasma CVD (HDPCVD) process, or the like or a combination thereof. The gate conductive layer may include doped polysilicon, metal, metal silicide, etc. For example, the gate conductive layer may, for example, include tungsten, aluminum, titanium, tantalum, tungsten silicide, titanium silicide, cobalt silicide, or the like or a combination thereof. Further, the gate conductive layer may be formed by a CVD process, a sputtering process, a PECVD process, an ALD process, or the like or a combination thereof. The gate mask layer may include a material having an etching selectivity with respect to the gate conductive layer and the gate insulation layer. For example, the gate mask layer may include silicon nitride, silicon oxynitride, titanium oxynitride, or the like or a combination thereof. Further, the gate mask layer may be formed by a CVD process, a PECVD process, a sputtering process, an ALD process, or the like or a combination thereof.

The gate mask layer, the gate conductive layer and the gate insulation layer are patterned to form a gate insulation layer pattern 306, a gate electrode 309 and a gate mask 312, respectively, which are sequentially stacked on the semiconductor substrate 300.

A first insulation layer (not shown) is then formed on the semiconductor substrate 300 to cover the gate mask 312. The first insulation layer is anisotropically etched to form gate spacers 315 on sidewalls of the gate insulation layer pattern 306, the gate electrode 309 and the gate mask 312. As a result, a gate structure 318 including the gate insulation layer pattern 306, the gate electrode 309, the gate mask 312 and the gate spacers 315 is formed on the active region of the semiconductor substrate 300. In one embodiment, the first insulation layer may include a material such as silicon nitride.

An ion implantation process is carried out using the gate structures 318 as an ion implantation mask to form a first contact region 321 and a second contact region 324 in portions of the semiconductor substrate 300 exposed adjacent to the gate structures 318. As a result, transistors including the gate structures 318, the first contact region 321 and the second contact region 324 are formed on the semiconductor substrate 300. For example, the first contact region 321 and the second contact region 324 may correspond to a source region and a drain region of the transistor, respectively.

Referring to FIG. 7, a first insulation interlayer 327 is formed on the semiconductor substrate 300 to cover the gate structures 318. In one embodiment, the first insulation interlayer 327 may include a material such as BPSG, PSG, TEOS, PE-TEOS, USG, FOX, SOG, HDP-CVD oxide, or the like or a combination thereof. Further, the first insulation interlayer 327 may be formed by a CVD process, a PECVD process, an ALD process, a HDPCVD process, or the like or a combination thereof.

The first insulation interlayer 327 is then partially etched by a photolithography process to form a first lower contact hole 330 and a second lower contact hole 333 that expose the first contact region 321 and the second contact region 324, respectively. For example, the first contact region 321 is exposed by the first lower contact hole 330 and the second contact region 324 is exposed by the second lower contact hole 333.

A first conductive layer 336 is formed on the first insulation interlayer 327 to fill up the first lower contact hole 330 and the second lower contact hole 333. In one embodiment, the first conductive layer 336 may, for example, include doped polysilicon, metal, conductive metal nitride, or the like or a combination thereof. For example, the first conductive layer 336 may include tungsten, titanium, titanium nitride, tantalum, tantalum nitride, aluminum, titanium aluminum nitride, tungsten nitride, tantalum nitride, aluminum nitride, or the like, either alone or in a combination thereof. Further, the first conductive layer 336 may be formed by a sputtering process, a CVD process, a PECVD process, an ALD process, an electron beam deposition process, a pulse laser deposition process, or the like or a combination thereof.

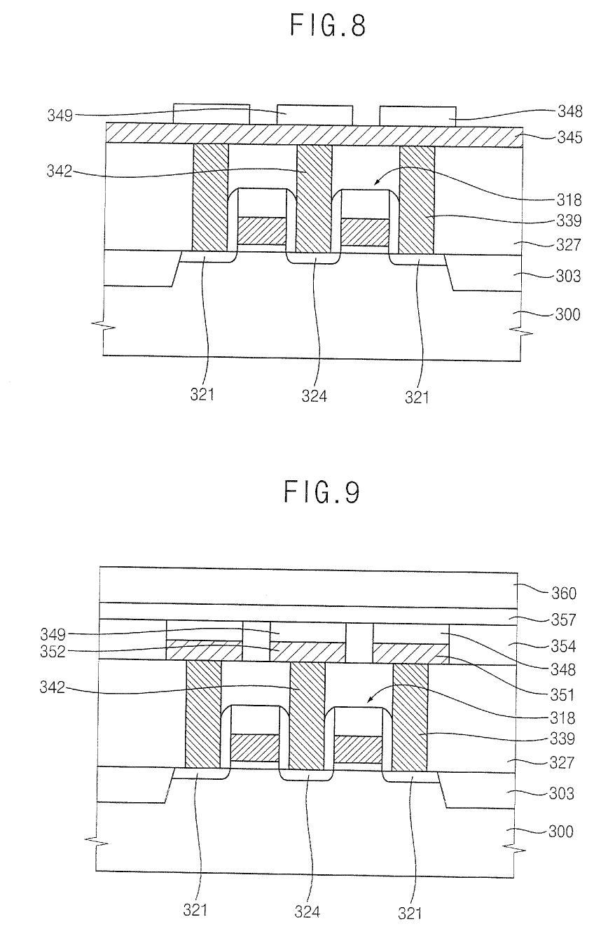

Referring to FIG. 8, the first conductive layer 336 is partially removed by a chemical mechanical polishing (CMP) process and/or an etch-back process until the first insulation interlayer 327 is exposed to form a first lower contact 339 in the first lower contact hole 330 and a second lower contact 342 in the second lower contact hole 330. Here, the first lower contact 339 is positioned on the first contact region 321, and the second lower contact 342 is positioned on the second contact region 324.

A second conductive layer 345 is then formed on the first insulation interlayer 327, the first lower contact 339 and the second lower contact 342. In one embodiment, the second conductive layer 345 may be formed by a CVD process, a sputtering process, an ALD process, an electron beam deposition process, a pulse laser deposition process, or the like or a combination thereof. The second conductive layer 345 may include a material such as doped polysilicon, metal, conductive metal nitride, or the like or a combination thereof.

A second insulation layer (not shown) is formed on the second conductive layer 345. The second insulation layer is then etched by a photolithography process to form a first insulation layer pattern 348 and a second insulation layer pattern 349 on the second conductive layer 345. In one embodiment, the second insulation layer may be formed by a CVD process, a PECVD process, an ALD process, a HDPCVD process, or the like or a combination thereof. In one embodiment, the second insulation layer may include a material such as a nitride, an oxynitride, or the like or a combination thereof. Further, the first insulation layer pattern 348 is arranged on a portion of the second conductive layer 345, beneath which the first lower contact 339 is placed, and the second insulation layer pattern 349 is arranged on a portion of the second conductive layer 345, beneath which the second lower contact 342 is positioned.

Referring to FIG. 9, the second conductive layer 345 is etched using the first insulation layer pattern 348 and the second insulation layer pattern 349 as an etching mask to simultaneously form a pad 351 and a lower wiring 352. In one embodiment, the pad 351 is positioned on the first lower contact 339 and the first insulation layer pattern 327, and the lower wiring 352 is positioned on the second lower contact 342 and the first insulation layer pattern 327. Thus, the pad 351 is electrically connected to the first contact region 321 through the first lower contact 339, and the lower wiring 352 is electrically connected to the second contact region 324 through the second lower contact 342.

A second insulation interlayer 354 is then formed on the first insulation interlayer 317 to cover the first insulation layer pattern 348 and the second insulation layer pattern 349. In one embodiment, the second insulation interlayer 354 may be formed by a CVD process, a PECVD process, an ALD process, a HDPCVD process, or the like or a combination thereof. In one embodiment, the second insulation interlayer may, for example, include BPSG, PSG, USG, SOG, FOX, TEOS, PE-TEOS, HDP-CVD oxide, or the like or a combination thereof.

The second insulation interlayer 354 is partially removed by a CMP process or an etch-back process until the first and the second insulation layer patterns 348 and 349 are exposed. In one embodiment, the second insulation interlayer 354 may be polished using a slurry including an abrasive that contains ceria having a high etching selectivity between oxide and nitride. Here, the first insulation layer pattern 348 and the second insulation layer pattern 349 may function as a polishing stop layer. The first insulation layer pattern 348 and the pad 351 are buried in the second insulation interlayer 354 by partially removing the second insulation interlayer 354. Simultaneously, the second insulation layer pattern 349 and the lower wiring 352 are buried in the second insulation interlayer 354.

A third insulation layer 357 is formed on the second insulation interlayer 354, the first insulation layer pattern 348 and the second insulation layer pattern 349. In one embodiment, the third insulation layer 357 may be formed by a CVD process, a PECVD process, an ALD process, a HDPCVD process, or the like or a combination thereof. In one embodiment, the third insulation layer 357 may, for example, include a nitride, an oxynitride, or the like or a combination thereof.

A sacrificial layer 360 including oxide is then formed on the third insulation layer 357. In one embodiment, the sacrificial layer 360 may be formed by a CVD process, a PECVD process, an ALD process, a HDPCVD process, or the like or a combination thereof.

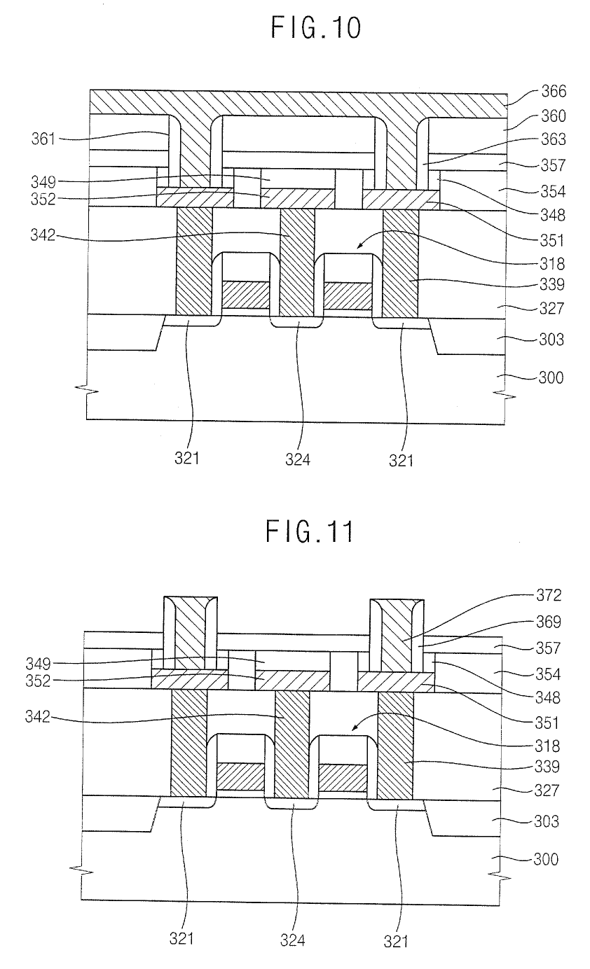

Referring to FIG. 10, the sacrificial layer 360, the third insulation layer 357 and the first insulation layer pattern 348 are partially etched by a photolithography process to form an opening 361 that exposes the pad 351.

A fourth insulation layer (not shown) is then formed on the pad 351 and the sacrificial layer 360 to fill up the opening 361. The fourth insulation layer is anisotropically etched to form a preliminary spacer 363 on a sidewall of the opening 361. In one embodiment, the fourth insulation layer may include silicon nitride.

A third conductive layer 366 is formed on the pad 351 and the sacrificial layer 360 to fill up the opening 361. In one embodiment, the third conductive layer 366 may include doped polysilicon, metal, metal nitride, or the like or a combination thereof. For example, the third conductive layer 366 may include tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, or the like, either alone or in a combination thereof. Further, the third conductive layer 366 may be formed by a sputtering process, a CVD process, a PECVD process, an ALD process, an electron beam deposition process, a pulse laser deposition process, or the like or a combination thereof.

Referring to FIG. 11, the third conductive layer 366 is partially removed by a planarization process until the sacrificial layer 360 is exposed to form a preliminary lower electrode 372 in the opening 361. The preliminary spacer 369 may be arranged between a sidewall of the preliminary lower electrode 372 and the sidewall of the opening 361.

The sacrificial layer 360 is then removed by an etch-back process to expose the second insulation layer 357. As a result, the preliminary lower electrode 372 and the preliminary spacer 369 protrude upwardly from an upper surface of the second insulation layer 357 as a filler shape.

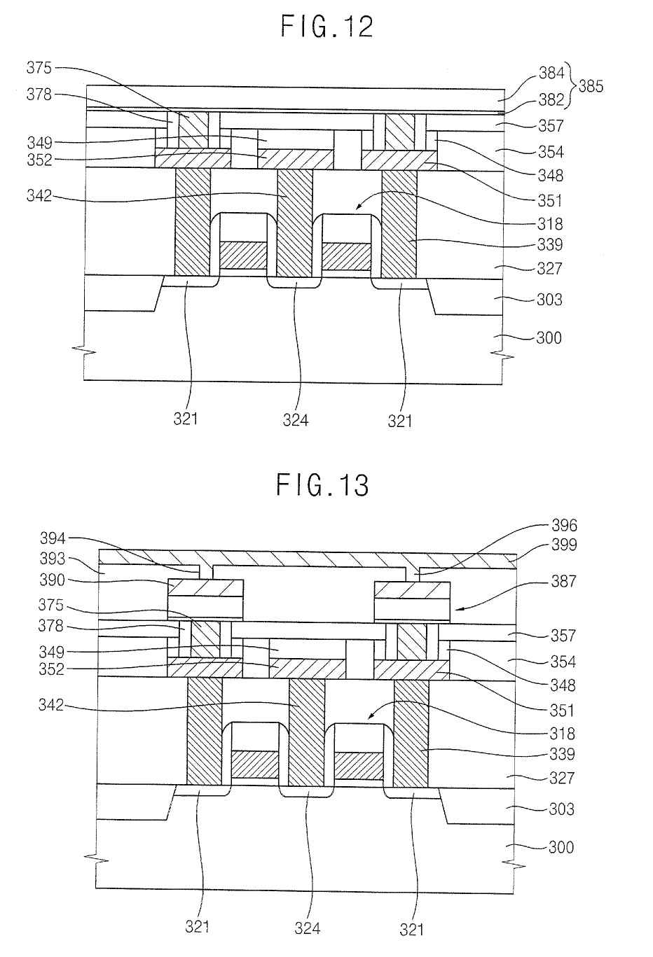

Referring to FIG. 12, the protruded portions of the preliminary lower electrode 372 and the preliminary spacer 369 are removed by a CMP process to simultaneously form a lower electrode 375 and a spacer 378 on the pad 351. In one embodiment, the lower electrode 375 and the spacer 378 may be formed using a slurry containing an abrasive that has ceria. Alternatively, a CMP process may be sufficiently carried out to partially remove the second insulation layer 257 during forming the lower electrode 375 and the spacer 378.

A phase-changeable layer 385 including a germanium-antimony-tellurium alloy is then formed on the second insulation layer 357, the lower electrode 375 and the spacer 378. In one embodiment, the phase-changeable layer 385 may include a lower phase-changeable layer 382 and an upper phase-changeable layer 384. In one embodiment, the lower phase-changeable layer 382 may include grains having a size of about 50 nm to about 80 nm and the upper phase-changeable layer 384 may include grains having a size of about 10 nm to about 30 nm. Processes for forming the phase-changeable layer 385 may be substantially the same as those described above with reference to FIGS. 4 and 5. Accordingly, a detailed description with respect to such processes is omitted for the sake of brevity.

Referring to FIG. 13, a fourth conductive layer (not shown) is then formed on the phase-changeable layer 385. In one embodiment, the fourth conductive layer may be formed by a sputtering process, an ALD process, an electron beam deposition process, a CVD process, a pulse laser deposition process, or the like or a combination thereof. In one embodiment, the fourth conductive layer may include a material such as doped polysilicon, metal, conductive metal nitride, or the like or a combination thereof.

The fourth conductive layer and the phase-changeable layer 385 are etched by a photolithography process to form an upper electrode 390 and a phase-changeable layer pattern 387. The phase-changeable layer pattern 387 is arranged on the second insulation layer 357, the lower electrode 378 and the spacer 375. The upper electrode 390 is arranged on the phase-changeable layer pattern 387.

A third insulation interlayer 393 including oxide is formed on the second insulation layer 357 to cover the upper electrode 390 with the third insulation interlayer 393. In one embodiment, the third insulation interlayer 393 may be formed by a CVD process, a PECVD process, an ALD process, a HDPCVD process, or the like or a combination thereof.

A photolithography process is then carried out on the third insulation interlayer 393 to form an upper contact hole 394 exposing the upper electrode 390. An upper contact 396 is formed on the upper electrode 390 to fill up the upper contact hole 394. Further, an upper wiring 399 is formed on the upper contact 396 and the third insulation interlayer 393. In one embodiment, the upper contact 396 and the upper wiring 399 may be simultaneously formed. Thus, the upper contact 396 and the upper wiring 399 may be formed as one body. The upper contact 396 and the upper wiring 399 may include a metal, conductive metal nitride, or the like or a combination thereof.

According to embodiments exemplarily described above, a phase-changeable layer includes a lower layer and an upper layer, stacked on the lower layer, having different grain sizes. The upper and lower layers of the phase-changeable layer may be formed using plasma that is generated by properly controlling an amount of hydrogen gas. Accordingly, the phase-changeable layer may have a structure where the lower layer has a grain size of not less than about 50 nm and the upper layer has a grain size of not more than about 30 nm by controlling the formation of the plasma.

Because the phase-changeable layer includes the upper layer having a dense structure of not less than about 80%, the phase-changeable layer may have a strong adhesion strength with respect to the lower layer and may further have good electrical characteristics.

Furthermore, the phase-changeable layer may be formed by relatively simple processes involving the introduction and purging of source gases. Therefore, a time and a cost associated with manufacturing a phase-changeable memory device including the phase-changeable layer may be remarkably reduced.

Exemplary embodiments of the present invention will now be described in a non-limiting way.

In a method of forming a phase-changeable layer in accordance with one embodiment, a first hydrogen gas is introduced into a reaction chamber into which a substrate is loaded at a first flow rate to form a first plasma. A cyclic chemical vapor deposition (CVD) process is primarily carried out using a first precursor, a second precursor and a third precursor in the reaction chamber in which the first plasma is formed to form a lower phase-changeable layer having a first grain size on the substrate. A second hydrogen gas is then introduced into the reaction chamber at a second flow rate less than the first flow rate to form second plasma. A cyclic chemical vapor deposition (CVD) process is secondarily carried out using the first, the second and the third precursors in the reaction chamber in which the second plasma is formed to form an upper phase-changeable layer having a second grain size smaller than the first grain size on the substrate, thereby forming a phase-changeable layer having strong adhesion strength with respect to the substrate and good electrical characteristic.

According to one example embodiment, a thickness ratio of the upper phase-changeable layer with respect to the lower phase-changeable layer may be about 1:8 to about 1:12.

According to another example embodiment, forming the first plasma may include introducing a first argon gas at a third flow rate together with the first hydrogen at the first flow rate into the reaction chamber. The first argon gas and the first hydrogen gas are then pre-heated. The pre-heated first argon gas and first hydrogen gas are stabilized. First hydrogen plasma and first argon plasma are generated from the stabilized first hydrogen gas and the stabilized first argon gas. Here, the first flow rate of the first hydrogen gas may be about 3.1 to about 5 times greater than the third flow rate of the first argon gas.

According to still another example embodiment, forming the second plasma may include introducing a second argon gas at a fourth flow rate together with the second hydrogen at the second flow rate into the reaction chamber. The second argon gas and the second hydrogen gas are then pre-heated. The pre-heated second argon gas and second hydrogen gas are stabilized. Second hydrogen plasma and second argon plasma are generated from the stabilized second hydrogen gas and the stabilized second argon gas. Here, the second flow rate of the second hydrogen gas may be about 0.2 to about 0.4 times greater than the fourth flow rate of the second argon gas.

In a method of manufacturing a phase-changeable memory device in accordance with another embodiment, a lower electrode is formed on a substrate. A lower phase-changeable layer, which includes germanium-antimony-tellurium and has a first grain size, is formed on the lower electrode. An upper phase-changeable layer, which includes germanium-antimony-tellurium and has a second grain size smaller than the first grain size, is formed on the lower phase-changeable layer. An upper electrode is then formed on the upper phase-changeable layer.

According to one example embodiment, the lower phase-changeable layer may be formed by a primary cyclic CVD process using a germanium precursor, an antimony precursor and a tellurium precursor under a first plasma atmosphere that is formed using a first hydrogen gas having a first flow rate.

According to another example embodiment, the upper phase-changeable layer may be formed by a secondary cyclic CVD process using a germanium precursor, an antimony precursor and a tellurium precursor under a second plasma atmosphere that is formed using a second hydrogen gas having a second flow rate less than the first flow rate.

According to the embodiments exemplarily described herein, the phase-changeable layer, which includes the lower layer and the upper layer having different grain sizes, may be readily formed using the plasma formed by properly controlling the amount of the hydrogen gases. That is, the phase-changeable layer, which includes the lower layer having the grain size of no less than about 50 nm and the upper layer having the grain size of no more than 30 nm, may be formed by controlling the plasma atmosphere. Therefore, the phase-changeable layer may have good electrical characteristics as well as strong adhesion strength.

Having exemplarily described embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A method of forming a phase-changeable layer, the method comprising:
loading a substrate into a reaction chamber;
introducing a first hydrogen gas into the reaction chamber at a first flow rate to form a first plasma;
performing a primary cyclic chemical vapor deposition (CVD) process, using a first precursor, a second precursor and a third precursor in the reaction chamber in which the first plasma forms a lower phase-changeable layer on the substrate, the lower phase-changeable layer including grains having a first grain size;
introducing a second hydrogen gas into the reaction chamber at a second flow rate less than the first flow rate to form a second plasma; and
performing a secondary cyclic CVD process using the first, the second and the third precursors in the reaction chamber in which the second plasma forms an upper phase-changeable layer on the lower phase-changeable layer, the upper phase-changeable layer including grains having a second grain size less than the first size.

2. The method of claim 1, wherein forming the first plasma comprises:
introducing a first argon gas into the reaction chamber at a third flow rate with the first hydrogen gas;
preheating the first argon gas and the first hydrogen gas;
stabilizing the preheated first argon gas and the preheated first hydrogen gas; and
forming a first hydrogen plasma and a first argon plasma from the stabilized first hydrogen gas and the stabilized first argon gas.

3. The method of claim 2, wherein the first flow rate is about 3.1 times to about 5.0 times greater than the third flow rate.

4. The method of claim 1, wherein forming the second plasma comprises:
introducing a second argon gas into the reaction chamber at a fourth flow rate with the second hydrogen gas;
preheating the second argon gas and the second hydrogen gas;
stabilizing the preheated second argon gas and the preheated second hydrogen gas; and
forming a second hydrogen plasma and a second argon plasma from the stabilized second hydrogen gas and the stabilized second argon gas.

5. The method of claim 4, wherein the second flow rate is about 0.2 times to about 0.4 times greater than the fourth flow rate.

6. The method of claim 1, wherein the first flow rate is about 3 times to about 6 times greater than the second flow rate.

7. The method of claim 2, wherein a thickness ratio of the upper phase-changeable layer to the lower phase-changeable layer is about 8:1 to about 12:1.

8. The method of claim 1, wherein the first grain size is about 50 nm to about 80 nm and the second grain size is about 10 nm to about 30 nm.

9. The method of claim 1, wherein the first precursor comprises a germanium precursor and wherein the germanium precursor comprises at least one selected from the group consisting of Ge(i-Pr)₃H, GeCl₄, Ge(Me)₄, Ge(Me)₄N₃, Ge(Et)₄, Ge(Me)₃NEt₂, Ge(i-Bu)₃H, Ge(nBu)₄, Sb(GeEt₃)₃ and Ge(Cp)₂.

10. The method of claim 1, wherein the second precursor comprises an antimony precursor wherein the antimony precursor comprises at least one selected from the group consisting of Sb(iBu)₃, SbCl₃, SbCl₅, Sb(Me)₃, Sb(Et)₃, Sb(iPr)₃, Sb(tBu)₃, Sb[N(Me)₂]₃ and Sb(Cp)₃.

11. The method of claim 1, wherein the third precursor comprises a tellurium precursor and wherein the tellurium precursor comprises at least one selected from the group consisting of Te(iBu)₂, TeCl₄, Te(Me)₂, Te(Et)₂, Te(nPr)₂, Te(iPr)₂ and Te(tBu)₂.

12. The method of claim 1, wherein forming the lower phase-changeable layer comprises:
forming a germanium-tellurium layer on the substrate according to a method comprising:
applying a first source gas including germanium to the substrate under the first plasma to form a germanium layer on the substrate; and
applying a second source gas including tellurium to the germanium layer to form the germanium-tellurium layer on the substrate;
forming an antimony-tellurium layer on the germanium-tellurium layer according to a method comprising:
applying a third source gas including antimony to the germanium-tellurium layer to form an antimony layer on the germanium-tellurium layer; and
applying a fourth source gas including tellurium to the antimony layer to form the antimony-tellurium layer on the germanium-tellurium layer; and
repeating forming the germanium-tellurium layer and forming the antimony-tellurium layer at least once.

13. The method of claim 12, further comprising introducing a first purge gas including hydrogen and argon into the reaction chamber before applying the second source gas.

14. The method of claim 12, further comprising introducing a second purge gas including hydrogen and argon into the reaction chamber before applying the third source gas.

15. The method of claim 12, further comprising introducing a third purge gas including hydrogen and argon into the reaction chamber before applying the fourth source gas.

16. The method of claim 12, further comprising introducing a fourth purge gas including hydrogen and argon into the reaction chamber after forming the antimony-tellurium layer.

17. The method of claim 1, wherein forming the upper phase-changeable layer comprises:
forming a germanium-tellurium layer on the lower phase-changeable layer according to a method comprising:
applying a first source gas including germanium to the lower phase-changeable layer under the second plasma atmosphere to form a germanium layer on the lower phase-changeable layer; and
applying a second source gas including tellurium to the germanium layer to form the germanium-tellurium layer on the lower phase-changeable layer;
forming an antimony-tellurium layer on the germanium-tellurium layer according to a method comprising:
applying a third source gas including antimony to the germanium-tellurium layer to form an antimony layer on the germanium-tellurium layer; and
applying a fourth source gas including tellurium to the antimony layer to form the antimony-tellurium layer on the germanium-tellurium layer; and
repeating forming the germanium-tellurium layer and forming the antimony-tellurium layer at least once.

18. A method of manufacturing a phase-changeable memory device, the comprising:
forming a lower electrode on a substrate;
forming a lower phase-changeable layer on the lower electrode, the lower phase-changeable layer including a germanium-antimony-tellurium alloy, wherein grains of the lower phase-changeable layer have a first grain size;
forming an upper phase-changeable layer on the lower phase-changeable layer, the upper phase-changeable layer including a germanium-antimony-tellurium alloy, wherein grains of the upper phase-changeable layer have a second grain size less than the first grain size; and
forming an upper electrode on the upper phase-changeable layer,
wherein the lower phase-changeable layer is formed by a primary CVD process using a germanium precursor, an antimony precursor and a tellurium precursor under a first plasma that is formed from a first hydrogen gas at a first flow rate, and
wherein the upper phase-changeable layer is formed by a secondary CVD process using a germanium precursor, an antimony precursor and a tellurium precursor under a second plasma that is formed from a second hydrogen gas at a second flow rate less than the first flow rate.

19. The method of claim 18, wherein the first gain size is about 50 nm to about 80 nm and the second grain size is about 10 nm to about 30 nm.

20. The method of claim 18, wherein the first flow rate is about 3 times to about 6 times greater than the second flow rate.

21. The method of claim 18, wherein a thickness ratio of the upper phase-changeable layer to the lower phase-changeable layer is about 8:1 to about 12:1.

22. The method of claim 18, wherein the substrate comprises a contact region and a lower wiring connected to the lower electrode.
